(19) United States
(12) Patent Application Publication
(10) Pub. No.: US 2020/0175916 A1
(43) Pub. Date: Jun. 4, 2020

(54) IMAGE DISPLAY DEVICE AND ITS MANUFACTURE METHOD

(71) Applicant: GOERTEK INC., Weifang City (CN)

(72) Inventors: Quanbo ZOU, Weifang City (CN); Zhe WANG, Weifang City (CN); Xiaoyang ZHANG, Weifang City (CN)

(21) Appl. No.: 16/615,068

(22) PCT Filed: May 31, 2017
(86) PCT No.: PCT/CN2017/086622

§ 371 Date: Nov. 19, 2019

(51) Int. Cl. G09G 3/3208; H01L 27/32; H01L 27/12; G02F 1/1347

(52) U.S. Cl. CPC G09G 3/3208; H01L 27/3248; G09G 2300/0426; G02F 1/1347; G09G 2340/0407; H01L 27/12

(57) ABSTRACT

An image display device comprises: a thin film transistor backplane (1), and a first resolution display panel (2), a second resolution display panel (4), a display driving chip (3) and an integrated display driver (5), which are fixed on the thin film transistor backplane (1); the display driving chip (3) is electrically connected to bonding pads (111) on the thin film transistor backplane (1), and is provided under the second resolution display panel (4); and the display driving chip (3) is used for driving the second resolution display panel (4); the integrated display driver (5) is used for driving the first resolution display panel (2); and a resolution of the first resolution display panel (2) is lower than a resolution of the second resolution display panel (4). The first resolution display panel (2) is driven by the standard drive manner of thin film transistor display panels, to realize low resolution displaying, and the second resolution display panel (4) is driven by the display driving chip (3), to improve the displaying quality of the display device.

### TECHNICAL FIELD

The present disclosure relates to the technical field of displays, and particularly relates to an image display device and its manufacture method.

### BACKGROUND ART

The concept of foveated imaging is proposed on the basis of the variable space resolution of the retina of human eyes. When human eyes are observing an object, the resolution is relatively high merely in the small area that is stared and interested, and the further away from the interested small area, the lower the resolution is. By such a regulatory mechanism of human eyes, the area interested by human eyes within the field of view can be observed with a high resolution, and the peripheral area of low resolution can provide a wide angular field and provide a broad field of view.

Such a technique, when applied to the field of displays, can decreases the working load of display devices especially GPUs. That is, when an object is being observed, in fact only the details of part of the object are totally clearly displayed with a high resolution, for example the area that occupies 10%-20% of the center of the sight line, while the vision in the peripheral region of the center of the sight line becomes increasingly blur, but can provide a person a wide field of view. The technique, used with other techniques such as eyeball tracking, can effectively reduce the requirements on the operational performance of the devices while ensuring the refresh rate, which is significant for the research and development for the products of the fields of virtual reality and augmented reality.

In recent years, some foveated imaging display devices have emerged. For example, the U.S. patent application with the publication date of Nov. 18, 2004 and the publication number of US 2004/0227703 discloses an image display device, wherein an optical display panel of the image display device comprises a center region and a peripheral region, and the center region has a pixel density higher than that of the peripheral region. However, the display panel that it discloses drives the pixel points of different pixel densities by using a driver on the display panel, and it's hard to achieve a sufficiently high center resolution by the driver on the display panel.

### SUMMARY OF THE DISCLOSURE

In order to improve the prior art and solve the above technical problem of the prior art, the main object of the present disclosure is to provide an image display device and its manufacture method.

In order to realize the above object, different embodiments individually teach the following multiple technical solutions:

According to one aspect of the present disclosure, there is provided an image display device, wherein, the image display device comprises: an image display device, comprising: a thin film transistor backplane, and a first resolution display panel, a second resolution display panel, a display driving chip and an integrated display driver, which are fixed on the thin film transistor backplane;

the display driving chip is electrically connected to bonding pads on the thin film transistor backplane, and is provided under the second resolution display panel;

the display driving chip is used for driving the second resolution display panel;

the integrated display driver is used for driving the first resolution display panel; and

a resolution of the first resolution display panel is lower than a resolution of the second resolution display panel.

Optionally, the second resolution display panel is located at a center region of the thin film transistor backplane, and the first resolution display panel is provided around the center region.

Optionally, an area of the first resolution display panel is larger than an area of the second resolution display panel.

Optionally, the image display device further comprises a transparent adhesive bond layer, wherein the transparent adhesive bond layer is used for encapsulating the first resolution display panel and the second resolution display panel.

Optionally, an outside of the transparent adhesive bond layer joins with a protecting plate.

Optionally, the second resolution display panel, along with the display driving chip under it, is provided at a top or bottom of the thin film transistor backplane.

Optionally, when the second resolution display panel, along with the display driving chip under it, is provided at the top of the thin film transistor backplane, a silicon substrate of the display driving chip is provided with through-silicon-vias (TSV) and/or chip side/wrap-around feed-throughs, and the through-silicon-vias (TSV) and/or chip side/wrap-around feed-throughs electrically connect the display driving chip and the bonding pads.

Optionally, when the second resolution display panel, along with the display driving chip under it, is provided at the bottom of the thin film transistor backplane, the thin film transistor backplane is provided with electrically conducting via holes, and the electrically conducting via holes electrically connect the display driving chip and the bonding pads.

Optionally, the thin film transistor backplane is a flexible backplane.

Optionally, the first resolution display panel and the second resolution display panel are a LCD display panel, an OLED display panel or an image display device panel combined by LCD and OLED.

Optionally, the resolution of the first resolution displaying region is 100-1000PPI, and the resolution of the second resolution displaying region is 500-5000PPI.

Optionally, the display driving chip is a CMOS integrated circuit chip, which comprises a silicon substrate and a CMOS integrated circuit layer that is provided on the silicon substrate.

According to another aspect of the present disclosure, there is provided a method for manufacturing an image display device, wherein the method comprises the steps of:

S110, forming a thin film transistor layer on a substrate, to make a thin film transistor backplane;

S120, providing bonding pads at part of the area of a top of the thin film transistor layer, to form a reserved area;

S130, providing a first resolution display panel at a top of the thin film transistor layer, and forming a first resolution displaying region at the area other than the reserved area;

S140, providing a second resolution display panel on a display driving chip, then assembling the display driving chip to a top of the reserved area, and electrically connecting the display driving chip and the bonding pads, to form a second resolution displaying region, wherein a resolution of the second resolution displaying region is higher than a resolution of the first resolution displaying region; and

S150, connecting an integrated display driver to the thin film transistor backplane, wherein the integrated display driver is used for driving the first resolution display panel, and the display driving chip is used for driving the second resolution display panel.

Optionally, in the Step S120, the reserved area is located at a center region of the thin film transistor layer, so that the second resolution displaying region is located at a center region of the thin film transistor backplane, and the first resolution displaying region is located at a peripheral region of the thin film transistor backplane.

Optionally, in the Step S140, the display driving chip is assembled by surface-mounting (SMT), flip-chip bonding, or anisotropic conductive film/paste (ACF/ACP).

Optionally, the method further comprises the step of:

S160, encapsulating by using a transparent adhesive bond layer the whole displaying region including the first resolution displaying region and the second resolution displaying region.

Optionally, the method further comprises the step of:

S170, joining an outside of the transparent adhesive bond layer with a protecting plate.

Optionally, the method comprises the steps of:

S210, providing bottom bonding pads on a substrate, providing on the substrate a transparent polymer layer that covers the bottom bonding pads, and forming a thin film transistor layer on the polymer layer, to make a thin film transistor backplane;

S220, providing at a top of the thin film transistor layer top bonding pads that correspond to the bottom bonding pads, wherein the top bonding pads and the bottom bonding pads are connected by electrically conducting via holes, and the area where the top bonding pads are located forms a reserved area;

S230, providing a first resolution display panel at the area of the top of the thin film transistor layer that is other than the reserved area, to form a first resolution displaying region;

S240, stripping off the substrate, to expose the bottom bonding pads;

S250, providing a second resolution display panel on an image display device driving chip, then assembling the display driving chip to a bottom of the polymer layer, and electrically connecting the display driving chip and the bottom bonding pads to form a second resolution displaying region, wherein a resolution of the second resolution displaying region is higher than a resolution of the first resolution displaying region; and

S260, connecting an integrated display driver to the thin film transistor backplane, wherein the integrated display driver is used for driving the first resolution display panel, and the display driving chip is used for driving the second resolution display panel.

Optionally, in the Step S220, the reserved area is located at a center region of the thin film transistor layer, so that the second resolution displaying region is located at a center region of the thin film transistor backplane, and the first resolution displaying region is located at a peripheral region of the thin film transistor backplane.

Optionally, before the Step S240, the method further comprises the step of:

S270, encapsulating the first resolution displaying region by using a transparent adhesive bond layer; and

after the Step S260, the method further comprises the step of:

S280, encapsulating the second resolution displaying region by using a transparent adhesive bond layer.

The present disclosure, by providing the first resolution display panel on the thin film transistor backplane to form the first resolution displaying region of a lower resolution, and by providing the second resolution display panel having the display driving chip on the thin film transistor backplane to form the second resolution displaying region of a higher resolution, obtains an image display device that has displaying of multiple resolution. Preferably, the first resolution displaying region is located at the peripheral region of the display for expanding the field of view, and the second resolution displaying region is located at the center region of the display for improving the displaying quality of the display. In such a manner, a user can obtain not only the high resolution displaying for the interested area, but also the low resolution displaying for the wide field of view, and thus the requirements on the operation performance can be lowered. The cost of the display device is reduced while the displaying quality is improved.

### BRIEF DESCRIPTION OF THE DRAWINGS

FIG. 1 is the schematic diagram of the structure of the image display device that is provided by the first embodiment of the present disclosure;

FIG. 2 is the enlarged schematic diagram of the structure in the block of FIG. 1;

FIG. 3 is the top view structural schematic diagram of the thin film transistor backplane of the image display device that is provided by the first embodiment of the present disclosure;

FIG. 4 is the schematic diagram of the structure of the image display device that is provided by the second embodiment of the present disclosure;

FIG. 5 is the flow chart of the method for manufacturing an image display device that is provided by the third embodiment of the present disclosure;

FIG. 6 is the flow chart of the method for manufacturing an image display device that is provided by the fourth embodiment of the present disclosure; and

FIG. 7a-7e are the schematic diagrams of manufacturing an image display device according to the method for manufacturing an image display device that is provided by the fourth embodiment of the present disclosure.

In the drawings, 1 denotes the thin film transistor backplane; 11 the thin film transistor layer; 111 the bonding pads; 112 the driver bonding pads; 12 the substrate; 13 the polymer layer; 131 the bottom bonding pads; 2 the first resolution display panel; 21 the top electrode; 22 the active layer; 23 the bottom electrode; 3 the display driving chip; 31 the CMOS integrated circuit layer; 32 the silicon substrate; 321 the through-silicon-vias (TSV); 322 the chip side/wrap-around feed-throughs; 4 the second resolution display panel; 41 the top electrode; 42 the active layer; 43 the bottom electrode; 5 the integrated display driver; 6 the transparent adhesive bond layer; 7 the protecting plate.

### DETAILED DESCRIPTION

In order to make the objects, the technical solutions and the advantages of the present disclosure clearer, the embodiments of the present disclosure will be described below in further detail in conjunction with the drawings.

### The First Embodiment

FIGS. 1-3 show the first embodiment of the image display device of the present disclosure. As shown in FIG. 1, the image display device comprises: a thin film transistor backplane 1, and a first resolution display panel 2, a second resolution display panel 4, a display driving chip 3 and an integrated display driver 5, which are fixed on the thin film transistor backplane 1.

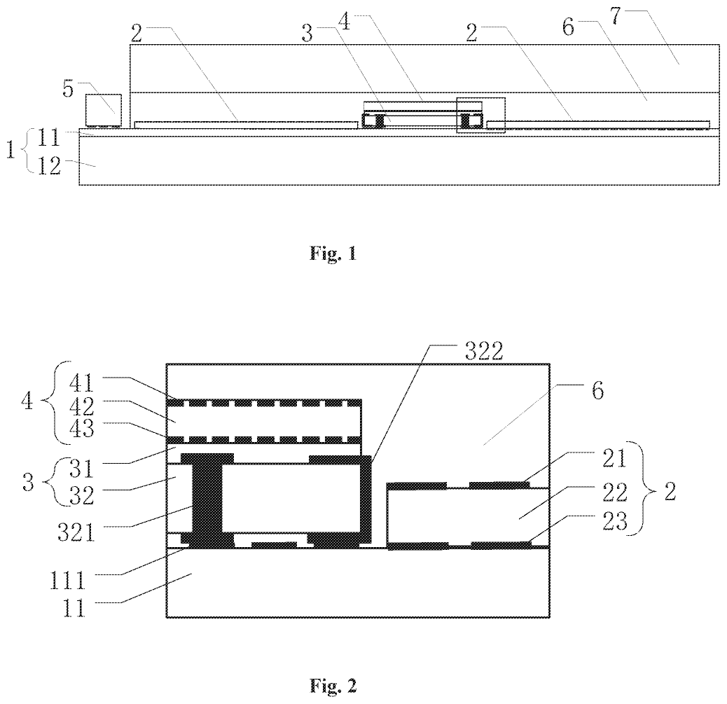

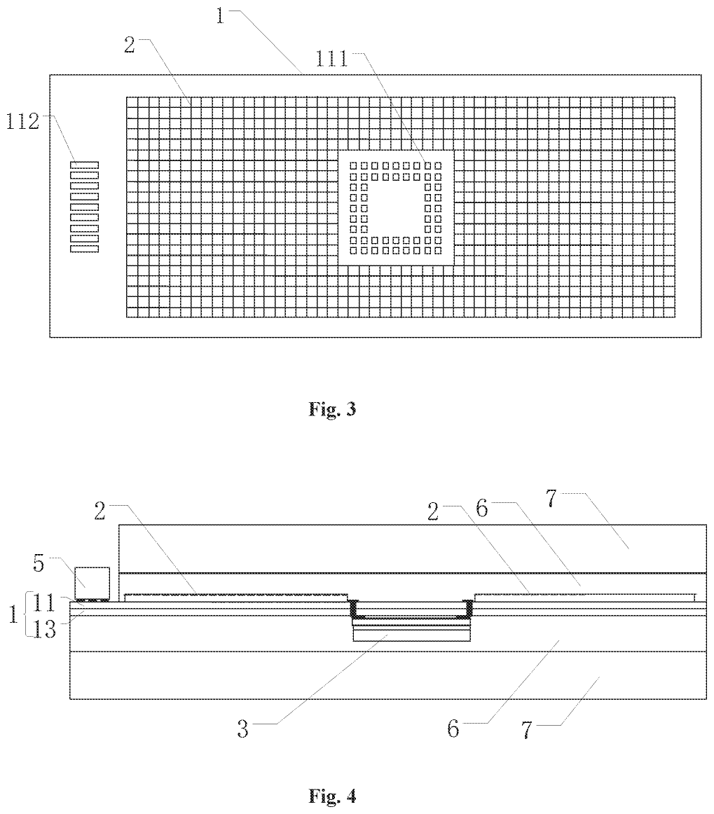

The thin film transistor backplane 1 comprises a thin film transistor layer 11 and a substrate 12, and the top of the thin film transistor layer 11 is provided with bonding pads 111 (see FIGS. 2 and 3).

The first resolution display panel 2 is directly provided on the thin film transistor layer 11 of the thin film transistor backplane 1.

The second resolution display panel 4 is installed on the display driving chip 3, and, along with the display driving chip 3, fixed on the thin film transistor backplane 1.

The display driving chip 3 is electrically connected to the bonding pads 111 on the thin film transistor backplane 1, and is provided under the second resolution display panel 4. The display driving chip 3 is used for driving the second resolution display panel 4.

The integrated display driver 5 is used for driving the first resolution display panel 2. The integrated display driver 5 may employ a conventional active thin film transistor configuration, and drive the first resolution display panel 2 by driving the thin film transistor. Optionally, the integrated display driver 5 is fixed on the thin film transistor backplane 1 by modes such as welding.

The resolution of the first resolution display panel 2 is lower than the resolution of the second resolution display panel 4.

The display device of the present disclosure comprises the first resolution display panel 2 and the second resolution display panel 4. The first resolution display panel 2 is directly provided on the thin film transistor backplane 1. The first resolution display panel 2 is driven by the standard drive manner of thin film transistor display panels. That is, the integrated display driver 5 controls the thin film transistor to drive the first resolution display panel 2. The first resolution display panel 2 realizes low resolution displaying, to provide the user a wide field of view. The second resolution display panel 4 is provided on the display driving chip 3. The second resolution display panel 4 is driven by the display driving chip 3. Specially, the display driving chip 3 acquires an electrical signal from the thin film transistor backplane 1 via the bonding pads 111, and drives the second resolution display panel 4 according to the electrical signal. The second resolution display panel has a higher resolution, to improve the displaying quality of the display device and realize the high resolution that conventional thin film transistor display panels cannot achieve, to construct the image display device of multiple resolutions.

FIG. 2 shows the enlarged view of the structure in the block of FIG. 1. As shown in FIG. 2, the first resolution display panel 2 comprises successively a top electrode 21, an active layer 22 and a bottom electrode 23, and is driven by thin film transistors. The second resolution display panel 4 comprises successively a top electrode 41, an active layer 42 and a bottom electrode 43. The second resolution display panel 4 possesses much denser pixel units than those of the first resolution display panel 2, and can provide image display of high resolution under the driving of the display driving chip 3. In the first embodiment, the display driving chip 3 is a CMOS integrated circuit chip comprising a CMOS integrated circuit layer 31 and a silicon substrate 32. The silicon substrate 32 is provided with through-silicon-vias (TSV) 321 and chip side/wrap-around feed-throughs 322 for electrical connection between the display driving chip 3 and the bonding pads 111 on the thin film transistor backplane 1. Optionally, the electrical connection may also be realized by using solely the through-silicon-vias (TSV) 321 or the chip side/wrap-around feed-throughs 322, detailed description thereof is omitted herewith. By establishing the electrical connection between the display driving chip 3 and the thin film transistor panel 1 by using the through-silicon-vias (TSV) 321 and/or the chip side/wrap-around feed-throughs 322, the image display device of the present disclosure has a compact structure and a small volume. It also facilitates the heat dissipation of the display driving chip 3 and enhances the reliability.

Preferably, FIG. 3 shows the top view of the thin film transistor backplane 1 of the first embodiment. In the top view, the first resolution display panel 2 has already been provided, and the display driving chip 3 having the second resolution display panel 4 has not been assembled. The assembling position of the second resolution display panel 4 is at the center region of the thin film transistor backplane 1, that is, the center region in FIG. 3 where the bonding pads 111 are provided. The first resolution display panel 2 is provided around the center region, as shown by the lattice square area in FIG. 3 that surrounds the center region. Furthermore, it can be seen in FIG. 3 that, a side of the thin film transistor backplane 1 is provided with driver bonding pads 112 for electrically connecting the integrated display driver 5.

The first resolution display panel 2 is located at the peripheral region of the display device, to provide a low resolution displaying of a wide field of view and expand the field of view. The second resolution display panel 4 is located at the center region of the image display device, to provide the high resolution displaying of the interested area and improve the displaying quality of the image display device. Not only the requirements by the user on details and visual field of display, but also the requirements on the operation performance of the display device can be satisfied, while the cost can be decreased and the displaying quality can be improved.

Preferably, the area of the first resolution display panel 2 is larger than the area of the second resolution display panel 4.

Preferably, the display further comprises a transparent adhesive bond layer 6. As shown in FIGS. 1 and 2, the transparent adhesive bond layer 6 is used for encapsulating the first resolution display panel 2 and the second resolution display panel 4. Specially, the transparent adhesive bond layer 6 packages the first resolution display panel 2, the display driving chip 3 and the second resolution display panel 4 together, to fix and protect them.

In the first embodiment, Referring to FIG. 1 and FIG. 2, the second resolution display panel 4, along with the display driving chip 3 under it, is provided at the top of the thin film transistor backplane 1. Optionally, the silicon substrate 32 of the display driving chip 3 is provided with through-silicon-vias (TSV) 321 and/or chip side/wrap-around feed-throughs 322, and the through-silicon-vias (TSV) 321 and/or the chip side/wrap-around feed-throughs 322 electrically connect the display driving chip 3 and the bonding pads 111.

### The Second Embodiment

FIG. 4 shows the second embodiment of the structure of the image display device of the present disclosure. Referring to FIG. 4, the second resolution display panel 4, along with the display driving chip 3 under it, is provided at the bottom of the thin film transistor backplane 1. The thin film transistor backplane 1 is provided with electrically conducting via holes, and the electrically conducting via holes electrically connect the display driving chip 3 and the bonding pads. Optionally, in the second embodiment, the thin film transistor backplane 1 comprises a thin film transistor layer 11 and a transparent polymer layer 13, the display driving chip 3 is provided at the bottom of the thin film transistor backplane 1, the electrically conducting via holes pass through the thin film transistor layer 11 and the transparent polymer layer 13 to electrically connect the display driving chip 3 and the bonding pads, and the light produced by the second resolution display panel 4 passes through the thin film transistor backplane 1 and then emits out. By providing the second resolution display panel 4, along with the display driving chip 3 under it, at the bottom of the thin film transistor backplane 1, it is not necessary to form through-silicon-vias (TSV) or chip side/wrap-around feed-throughs on the silicon substrate of the display driving chip 3. This reduces the process cost while the displaying quality of the image display device is not affected.

Similarly, in the second embodiment, the transparent adhesive bond layer 6 is also provided, and the transparent adhesive bond layer 6 packages both the first resolution display panel 2 located at the top of the thin film transistor backplane 1 and the second resolution display panel 4 and the display driving chip 3 located at the bottom of the thin film transistor backplane 1.

More preferably, in the first embodiment and the second embodiment, there is a protecting plate 7, such as a glass plate, on the outside of the transparent adhesive bond layer 6 to further improve the protection effect. As shown in FIG. 1, the protecting plate 7 is provided on the outside of the transparent adhesive bond layer 6 on the upper side of the display. Optionally, as shown in FIG. 4, two protecting plates 7 are provided, on the outsides of the transparent adhesive bond layers 6 on the upper and lower sides of the image display device.

Preferably, the thin film transistor backplane 1 is a flexible backplane, and the protecting plate 7 is configured to be a flexible protecting plate thin enough to cause the final image display device of the present disclosure to be flexible.

Preferably, the first resolution display panel 2 and the second resolution display panel 4 are a LCD display panel, an OLED display panel or an image display device panel combined by LCD and OLED.

Preferably, the resolution of the first resolution displaying region is 100-1000PPI, and the resolution of the second resolution displaying region is 500-5000PPI.

### The Third Embodiment

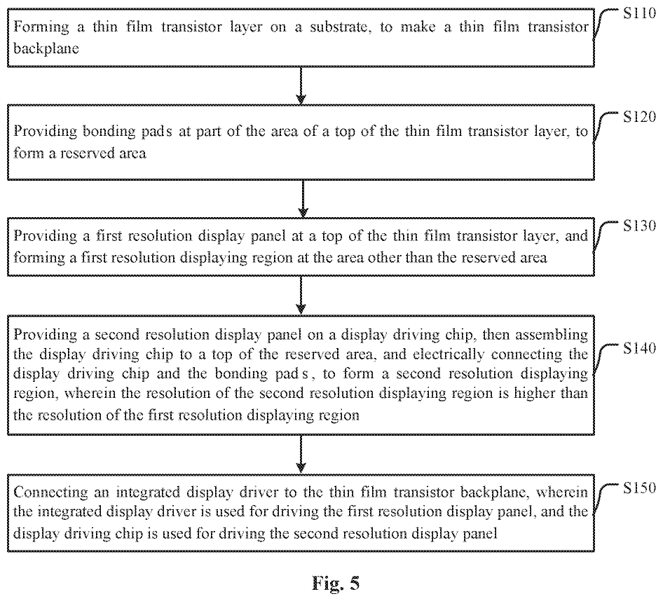

The present disclosure further discloses a method for manufacturing an image display device. As shown by the flow chart of FIG. 5, the method comprises the steps of:

S110, forming a thin film transistor layer on a substrate to make a thin film transistor backplane. In this step, the thin film transistor backplane may employ standard and known manufacturing processes of thin film transistor backplanes;

S120, providing bonding pads at part of the area of the top of the thin film transistor layer to form a reserved area;

S130, providing a first resolution display panel at the top of the thin film transistor layer, and forming a first resolution displaying region at the area other than the reserved area. The thin film transistor backplane obtained after the processing of this step is shown in FIG. 3;

S140, providing a second resolution display panel on a display driving chip, then assembling the display driving chip to the top of the reserved area, and electrically connecting the display driving chip and the bonding pads, to form a second resolution displaying region, wherein the resolution of the second resolution displaying region is higher than the resolution of the first resolution displaying region; and

S150, connecting an integrated display driver to the thin film transistor backplane, wherein the integrated display driver is used for driving the first resolution display panel, and the display driving chip is used for driving the second resolution display panel. By providing the display driving chip for driving the second resolution display panel, the image display device with multiple resolutions of the present disclosure overcomes the defect of conventional processes of thin film transistor backplanes that high resolutions cannot be achieved.

Preferably, in the Step S120, the reserved area is located at the center region of the thin film transistor layer, so that the second resolution displaying region is located at the center region of the thin film transistor backplane, and the first resolution displaying region is located at the peripheral region of the thin film transistor backplane.

Preferably, in the Step S140, the display driving chip is assembled by the method of surface-mounting (SMT), flip-chip bonding, or anisotropic conductive film/paste (ACF/ACP).

Preferably, the method further comprises the step of:

S160, encapsulating by using a transparent adhesive bond layer the whole displaying region including the first resolution displaying region and the second resolution displaying region; Particularly, encapsulating by using a transparent adhesive bond layer the first resolution display panel, the display driving chip and the second resolution display panel, which are located at the top of the thin film transistor backplane.

Preferably, the method further comprises the step of:

S170, joining the outside of the transparent adhesive bond layer with a protecting plate to further improve the protection to the image display device of the present disclosure.

### The Fourth Embodiment

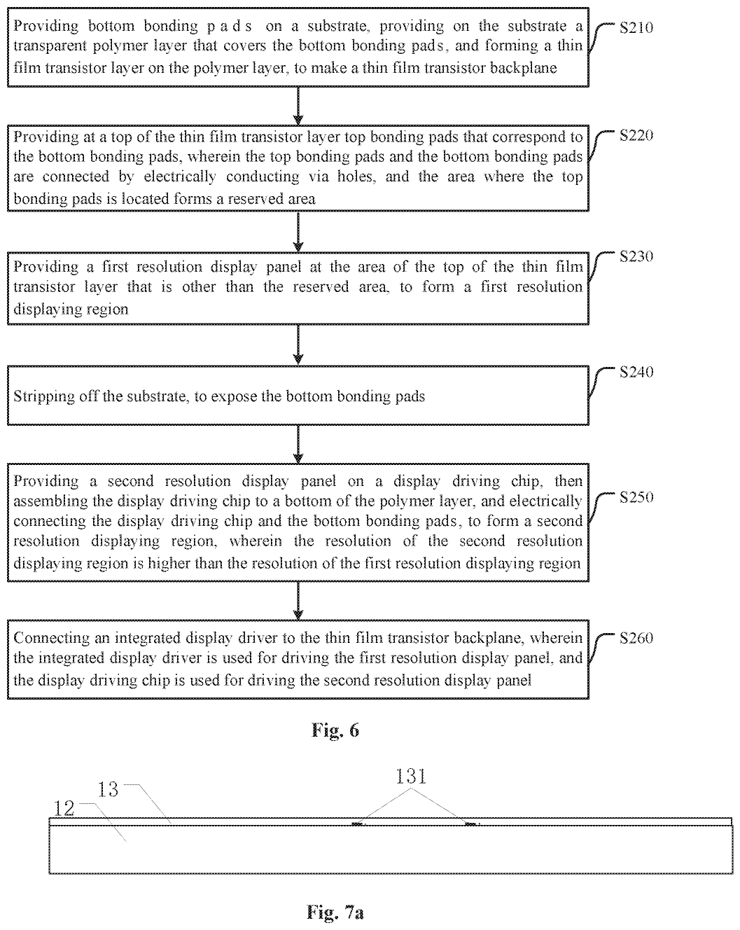

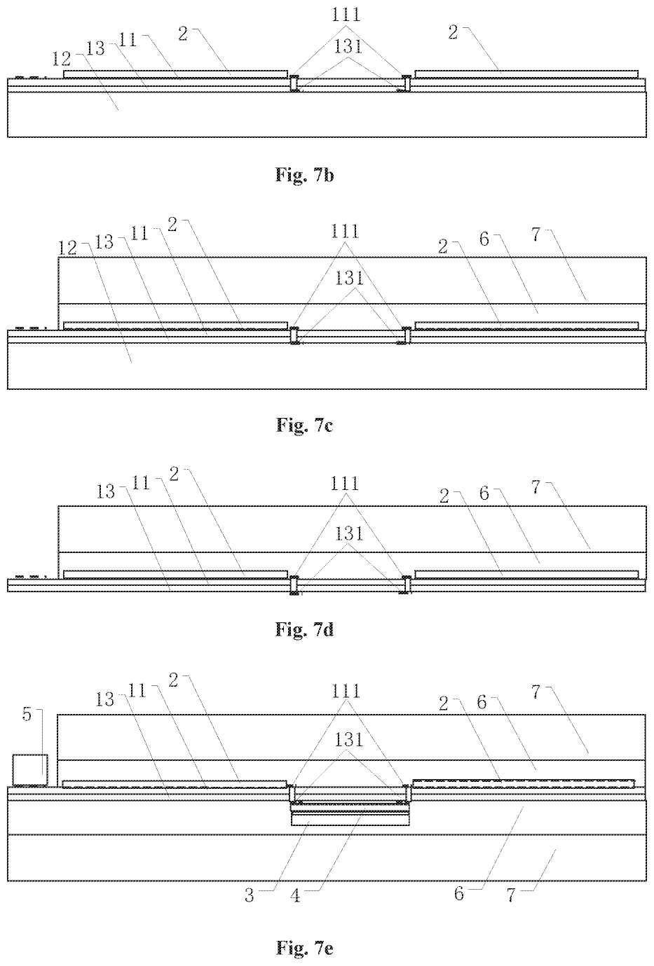

FIGS. 6-7e show another embodiment of the method for manufacturing an image display device of the present disclosure. As shown in FIGS. 6-7e, the method comprises the steps of:

S210, providing bottom bonding pads 131 on a substrate 12, providing on the substrate 12 a transparent polymer layer 13 that covers the bottom bonding pads 131, and forming a thin film transistor layer 11 on the polymer layer 13, to make a thin film transistor backplane. As shown in FIG. 7a, the substrate 12 is a glass plate substrate, and the transparent polymer layer 13 is polyimide or silica gel. The transparent polymer layer 13 has a thickness of 1-100 micrometers, and has a good flexibility;

S220, providing at the top of the thin film transistor layer 11 top bonding pads 111 that correspond to the bottom bonding pads 131, wherein the top bonding pads 111 and the bottom bonding pads 131 are connected by electrically conducting via holes. As shown in FIG. 7b, the electrically conducting via holes pass through the thin film transistor layer 11 and the polymer layer 13 to connect the top bonding pads 111 and the bottom bonding pads 131, and a reserved area is formed by the area where the top bonding pads 111 are located.

S230, providing a first resolution display panel 2 at the top of the thin film transistor layer 11, and maintaining the reserved area at the top of the thin film transistor layer 11 empty, thereby forming a first resolution displaying region at the area other than the reserved area, as shown in FIG. 7b;

S240, stripping off the glass plate substrate 12 to expose the bottom bonding pads 131 at the bottom of the polymer layer 13, as shown in FIGS. 7c-7d. The glass plate substrate 12 may be stripped off by laser illuminating or by infrared or ultraviolet irradiation;

S250, providing the second resolution display panel 4 on the display driving chip 3, assembling the display driving chip 3 to the bottom of the polymer layer 13, and electrically connecting the display driving chip 3 and the bottom bonding pads 131, to form a second resolution displaying region, wherein the resolution of the second resolution displaying region is higher than the resolution of the first resolution displaying region; and

S260, connecting an integrated display driver 5 to a predetermined area of the thin film transistor backplane, wherein the integrated display driver 5 is used to drive the first resolution display panel 2 for providing low resolution displaying, and the display driving chip 3 is used to drive the second resolution display panel 4 for providing high resolution displaying, as shown in FIG. 7e.

Preferably, in the Step S220, the reserved area is located at the center region of the thin film transistor layer 11, so that the second resolution displaying region is located at the center region of the thin film transistor backplane, and the first resolution displaying region is located at the peripheral region of the thin film transistor backplane. The first resolution displaying region of low resolution can provide a wide field of view, and the second resolution displaying region of high resolution can improve the displaying quality of the interested area.

Preferably, before the Step S240, the method further comprises the step of:

S270, encapsulating the first resolution displaying region by using a transparent adhesive bond layer 6, thereby providing a good protection by the transparent adhesive bond layer to the first resolution displaying region before the sequent process steps, as shown in FIG. 7c.

Preferably, after the Step S260, the method further comprises the step of:

S280, encapsulating the second resolution displaying region by using a transparent adhesive bond layer 6.

Preferably, the method further comprises providing a protecting plate 7 on the outside of the transparent adhesive bond layer 6.

The above are only special embodiments of the present disclosure. In accordance with the teaching of the present disclosure, a person skilled in the art can make other modifications or variations on the basis of the above embodiments. A person skilled in the art should appreciate that, the above special descriptions are only for the purpose of better explaining the present disclosure, and the protection scope of the present disclosure should be subject to the protection scope of the claims.

What is claimed is:

1. An image display device, comprising: a thin film transistor backplane, and a first resolution display panel, a second resolution display panel, a display driving chip and an integrated display driver, which are fixed on the thin film transistor backplane;
the display driving chip is electrically connected to bonding pads on the thin film transistor backplane, and is provided under the second resolution display panel;
the display driving chip is used for driving the second resolution display panel;
the integrated display driver is used for driving the first resolution display panel; and
the resolution of the first resolution display panel is lower than the resolution of the second resolution display panel.

2. The image display device according to claim 1, wherein, the second resolution display panel is located at a center region of the thin film transistor backplane, and the first resolution display panel is provided around the center region.

3. The image display device according to claim 1, wherein, an area of the first resolution display panel is larger than an area of the second resolution display panel.

4. The image display device according to claim 1, wherein, the image display device further comprises a transparent adhesive bond layer, wherein the transparent adhesive bond layer is used for encapsulating the first resolution display panel and the second resolution display panel.

5. The image display device according to claim 4, wherein, an outside of the transparent adhesive bond layer joins with a protecting plate.

6. The image display device according to claim 1, wherein, the second resolution display panel, along with the display driving chip under it, is provided at a top or bottom of the thin film transistor backplane.

7. The image display device according to claim 6, wherein, when the second resolution display panel, along with the display driving chip under it, is provided at the top of the thin film transistor backplane, a silicon substrate of the display driving chip is provided with through-silicon-vias (TSV) and/or chip side/wrap-around feed-throughs, and the through-silicon-vias (TSV) and/or chip side/wrap-around feed-throughs electrically connect the display driving chip and the bonding pads.

8. The image display device according to claim 6, wherein, when the second resolution display panel, along with the display driving chip under it, is provided at the bottom of the thin film transistor backplane, the thin film transistor backplane is provided with electrically conducting via holes, and the electrically conducting via holes electrically connect the display driving chip and the bonding pads.

9. The image display device according to claim 1, wherein, the thin film transistor backplane is a flexible backplane.

10. The image display device according to claim 1, wherein, the first resolution display panel and the second resolution display panel are a LCD display panel, an OLED display panel or an image display device panel combined by LCD and OLED.

11. The image display device according to claim 1, wherein, the resolution of the first resolution displaying region is 100-1000PPI, and the resolution of the second resolution displaying region is 500-5000PPI.

12. The image display device according to claim 1, wherein, the display driving chip is a CMOS integrated circuit chip, which comprises a silicon substrate and a CMOS integrated circuit layer that is provided on the silicon substrate.

13. A method for manufacturing an image display device, wherein, the method comprises the steps of:
S110, forming a thin film transistor layer on a substrate, to make a thin film transistor backplane;
S120, providing bonding pads at part of the area of a top of the thin film transistor layer, to form a reserved area;
S130, providing a first resolution display panel at a top of the thin film transistor layer, and forming a first resolution displaying region at the area other than the reserved area;
S140, providing a second resolution display panel on an image display device driving chip, then assembling the display driving chip to a top of the reserved area, and electrically connecting the display driving chip and the bonding pads, to form a second resolution displaying region, wherein a resolution of the second resolution displaying region is higher than a resolution of the first resolution displaying region; and
S150, connecting an integrated display driver to the thin film transistor backplane, wherein the integrated display driver is used for driving the first resolution display panel, and the display driving chip is used for driving the second resolution display panel.

14. The method according to claim 13, wherein,
in the Step S120, the reserved area is located at a center region of the thin film transistor layer, so that the second resolution displaying region is located at a center region of the thin film transistor backplane, and the first resolution displaying region is located at a peripheral region of the thin film transistor backplane.

15. The method according to claim 13, wherein,
in the Step S140, the display driving chip is assembled by surface-mounting (SMT), flip-chip bonding, or anisotropic conductive film/paste (ACF/ACP).

16. The method according to claim 13, wherein, the method further comprises the step of:
S160, encapsulating by using a transparent adhesive bond layer the whole displaying region including the first resolution displaying region and the second resolution displaying region.

17. The method according to claim 16, wherein, the method further comprises the step of:
S170, joining an outside of the transparent adhesive bond layer with a protecting plate.

18. A method for manufacturing an image display device, wherein, the method comprises the steps of:
S210, providing bottom bonding pads on a substrate, providing on the substrate a transparent polymer layer that covers the bottom bonding pads, and forming a thin film transistor layer on the polymer layer, to make a thin film transistor backplane;
S220, providing at a top of the thin film transistor layer top bonding pads that correspond to the bottom bonding pads, wherein the top bonding pads and the bottom bonding pads are connected by electrically conducting via holes, and the area where the top bonding pads is located forms a reserved area;
S230, providing a first resolution display panel at the area of the top of the thin film transistor layer that is other than the reserved area, to form a first resolution displaying region;
S240, stripping off the substrate, to expose the bottom bonding pads;
S250, providing a second resolution display panel on an image display device driving chip, then assembling the display driving chip to a bottom of the polymer layer, and electrically connecting the display driving chip and the bottom bonding pads, to form a second resolution displaying region, wherein a resolution of the second resolution displaying region is higher than a resolution of the first resolution displaying region; and
S260, connecting an integrated display driver to the thin film transistor backplane, wherein the integrated display driver is used for driving the first resolution display panel, and the display driving chip is used for driving the second resolution display panel.

19. The method according to claim 18, wherein,
in the Step S220, the reserved area is located at a center region of the thin film transistor layer, so that the second resolution displaying region is located at a center region of the thin film transistor backplane, and the first resolution displaying region is located at a peripheral region of the thin film transistor backplane.

20. The method according to claim 18, wherein, before the Step S240, the method further comprises the step of:
S270, encapsulating the first resolution displaying region by using a transparent adhesive bond layer; and
after the Step S260, the method further comprises the step of:
S280, encapsulating the second resolution displaying region by using a transparent adhesive bond layer.
